(19) United States
(12) Patent Application Publication
(10) Pub. No.: US 2007/0062574 A1
(43) Pub. Date: Mar. 22, 2007

(54) Electrode wire material and solar cell having connection lead wire formed of the wire material

(75) Inventors: Kazuhiro Shiomi, Osaka (JP); Toshiaki Fujita, Osaka (JP); Masaaki Ishio, Osaka (JP)

Correspondence Address: NEOMAX CO., LTD.;C/O KEATING & BENNETT, LLP, 8180 GREENSBORO DRIVE, SUITE 850, MCLEAN, VA, 22102, US

(73) Assignee: NEOMAX MATERIALS CO., LTD., Osaka (JP)

(21) Appl. No.: 10/558,214

(22) PCT Filed: May 19, 2004
(86) PCT No.: PCT/JP04/06725

§ 371 Date: Jul. 26, 2006

(30) Foreign Application Priority Data
May 22, 2003 (JP) 2003-144205

(51) Int. Cl. H01L 31/00

(52) U.S. Cl. 136/256

(57) ABSTRACT

An electrode wire material that can be used in a solar cell is produced without using flattening rolls or endless belts and has excellent solderability. The electrode wire material includes a core material formed of a strip-like conductive material and a hot-dip solder plated layer formed on a surface of the core material. A recessed portion for storing molten solder is formed in the core material along the longitudinal direction and the hot-dip solder plated layer is filled in the recessed portion. The recessed portion for storing molten solder preferably has an opening width in the lateral direction of the core material of about 90% or more of the width of the core material. The core material is preferably formed of a clad material including an interlayer of a low thermal expansion Fe alloy and copper layers formed on both surfaces of the interlayer.

### TECHNICAL FIELD

The invention relates to an electrode wire material to be used as a connection lead wire of electronic parts such as solar cells.

### BACKGROUND ART

Solar cells respectively comprise a semiconductor substrate of a silicon semiconductor having PN junction and connection lead wires soldered to a plurality of front face electrodes formed linearly on the surface of the semiconductor substrate and in general, a plurality of such solar cells are connected in series so as to obtain a desired electromotive force. The series connection is done by connecting connection lead wires soldered to a front electrode of one solar cell to a rear electrode of another solar cell.

The electrode wire material before the connection lead wires being soldered to the front electrode of the semiconductor substrate comprises a core material 51 of a pressed copper wire pressed to be flat by rolling a copper wire halving a circular cross section and hot-dip solder plated layers 52, 52 formed on the both faces of the core material. As shown in FIG. 5, the hot-dip solder plated layers 52, 52 are formed on both faces of the core material 51 by hot dip plating method, that is, the layers formed by passing the core material 51 whose surface is cleaned by acid pickling or the like through a molten solder bath. The hot-dip solder plated layer 52 has a hill-like shape expanded toward the center part from the end parts as shown in FIG. 5 by surface tension at the time of solidification of the molten solder deposited on the core material 51.

At the time of soldering the electrode wire material to the semiconductor substrate, the heating temperature is strictly controlled to be a temperature around the melting point of the solder material. The reason for that is because the thermal expansion coefficient of copper forming the core material 51 of the electrode wire material and that of, for example, silicon forming the semiconductor substrate are quite different from each other. That is, soldering is carried out at a low temperature so as to suppress the heat stress, which causes cracking in a costly semiconductor substrate, as much as possible. The heating at the time of soldering is generally carried out by heating with a hot plate on which the semiconductor substrate is mounted and heating the electrode wire material mounted on the semiconductor substrate from the upper side in combination.

However, as shown in FIG. 5, since the hot-dip solder plated layer of the electrode wire material has the hill-like shape expanded in the center part, at the time of soldering the electrode wire material to the front electrodes of the semiconductor substrate, the contact region of the solder belt formed previously on the surface of the semiconductor substrate for easy electric communication to the front electrodes and the hot-dip solder plated layer becomes narrow and the heat transmission from the semiconductor substrate side to the hot-dip solder plated layer easily tends to be insufficient. In addition to that, the soldering temperature decreases. Hence, soldering failure tends to occur. In an extreme case, there occurs a problem that the connection lead wires come out of the semiconductor substrate during handling the solar cell.

Therefore, various means have been tried in hot dip plating steps so as to make the hot-dip solder plated layer of the electrode wire material even in the thickness as much as possible. For example, JP 7-243014-A (Patent Document 1) describes a technique of solidifying the plated layer under the condition that the strip-like material led out of a hot dip plating bath is rolled on a roll while the plated layer deposited on the surface of the material is still in molten state or solidifying the plated layer while the strip-like material adhering the plated layer being sandwiched between a pair of endless belts. On the other hand, for example, JP 60-15937-A (Patent Document 2) proposes, as a conductive material with a small difference of the thermal expansion coefficient from that of the semiconductor material, a clad material composed of a plate of Invar (typical composition: Fe-36% Ni) of an Fe—Ni alloy, and copper plates unitedly formed on the both faces of the Invar plate.
Patent Document 1: Japanese Unexamined Patent Publication No. 7-243014
Patent Document 2: Japanese Unexamined Patent Publication No. 60-15937

### DISCLOSURE OF THE INVENTION

Problems to be Solved by the Invention

As described above, to improved the solderability of an electrode wire material to be soldered to a semiconductor substrate, the hot-dip solder plated layer formed on the electrode wire material is better to be made as flat as possible. However as described in Patent Document 1, to solidify the plated layer in flat state, it is required to prepare flattening rolls and endless belts, strictly control the tension of the core material (a strip-like material) which is an object material to be plated, and carry out complicated operations for changing the roll diameter and the belt length corresponding to the plating temperature and plating speed.

In view of the foregoing, it is an object of the invention to provide an electrode wire material which can be produced without using flattening solidifying means such as flattening rolls and endless belts and has excellent solderability, and a solar cell of which the connection lead wire is formed of the electrode wire material.

Means for Solving the Problems

An electrode wire material of the invention comprises a core material formed of a strip-like conductive material and a hot-dip solder plated layer formed on a surface of the core material. The core material has a recessed part formed therein along the longitudinal direction for storing molten solder and the hot-dip solder plated layer is filled in the recessed part.

According to the electrode wire material, since the recessed part for storage of molten solder are formed in the core material of the electrode wire material, when the molten solder is supplied to the recessed part is solidified, even if the surface tension works on the molten solder, the center portion of the molten solder is hardly swollen and thus the hot-dip solder plated layer tends to be flat. Hence, when the electrode wire material is mounted on the surface of the soldered part such as a solder belt of the semiconductor substrate in such a manner that the hot-dip solder plated layer makes contact with the soldered part, the contact region of the soldered part and the hot-dip solder plated layer is widened as compared with that of a conventional hill-like hot-dip solder plated layer, and thus the thermal conductivity is improved. Therefore, the solderability of the electrode wire material is improved and excellent bondability can be obtained.

With respect to the electrode wire material, when the molten solder supplied to the recessed part for storing molten solder solidifies, to make the molten solder easily flat in the entire width of the core material, it is desirable to form the recessed part for storing molten solder in such a manner that the opening width of the recessed part in the lateral direction of the core material is 90% or higher in the width of the core material. Further, in order to make the opening width of the recessed part for storing molten solder wide, it is desirable to form a recessed part for storing molten solder in a recessed side of the core material which is formed to be dish-like or curved cross-sectional shape in the perpendicular direction in relation to the longitudinal direction. Since such a shape is simple and easy for forming, it is excellent in industrial productivity.

The core material is desirably formed of a clad material comprising copper layers formed on both faces of an interlayer composed of a low thermal expansion Fe alloy selected from an Fe—Ni alloy such as Invar or an Fe—Ni—Co alloy such as Kovar (trade name). Use of such a clad material for the core material makes it possible to remarkably decrease the thermal expansion coefficient as compared with that of a copper material, and then the thermal stress generated in the semiconductor substrate, which is soldered with the electrode wire material, can be decreased, and hence, a semiconductor substrate with further thinner thickness is made usable to lead to weight saving of the semiconductor substrate and cost down of the material.

The hot-dip solder plated layer can be formed of a lead-free solder material having a melting point of 130° C. or higher and 300° C. or lower. Such a solder scarcely causes environmental pollution with lead and its melting point is low, so that the solder is advantageous in a point that thermal stress is hardly generated when the electrode wire material is soldered to the semiconductor substrate.

Further, a solar cell of the invention comprises a semiconductor substrate formed of a semiconductor having PN junction and a connection lead wire soldered to a plurality of front face electrodes formed on the surface of the semiconductor substrate. The connection lead wire is composed of the electrode wire material soldered to a plurality of front face electrodes formed on the semiconductor substrate with the hot-dip solder plated layer.

According to the solar cell, since the connection lead wire is composed of the electrode wire material soldered to the front face electrodes on the semiconductor substrate with the flatten hot-dip solder plated layer filled in the recessed part for storing molten solder, the connection lead wire is firmly bonded to the semiconductor substrate and hardly come out of the semiconductor substrate, and thus the solar cell has excellent durability.

Effects of the Invention

According to the electrode wire material of the invention, since the hot-dip solder plated layer filled in the recessed part for storing molten solder in the core material is easy to be flatten in the surface as compared with conventional one, it is made possible to improve the solderability to the soldered part formed on a semiconductor substrate or the like and then improve the bonding durability of the electrode wire material.

Further, according to the solar cell of the invention, since the connection lead wire is formed of the electrode wire material of which the hot-dip solder plated layer filled in the recessed part for storing molten solder is soldered to a plurality of the front face electrodes of the semiconductor substrate, the connection lead wire is firmly bonded to the semiconductor substrate and hardly come out of the semiconductor substrate, and then the solar cell enhances the handling properties and durability.

### BRIEF DESCRIPTION OF THE DRAWINGS

FIG. 1 is a transverse cross-sectional view of an electrode wire material according to one embodiment of the invention.

FIG. 2 is a transverse cross-sectional view of an electrode wire material according to another embodiment of the invention.

FIG. 3 is a transverse cross-sectional view of an electrode wire material according to the other embodiment of the invention.

FIG. 4 is a schematic perspective view of a solar cell according to an embodiment of the invention.

FIG. 5 is a transverse cross-sectional view of a conventional electrode wire material.

### BEST MODE FOR CARRYING OUT OF THE INVENTION

FIG. 1 shows an electrode wire material according to the first embodiment of the invention and the electrode wire material 1 comprises a strip-like core material 2 formed of a conductive material and hot-dip solder plated layers 5A, 5B formed on the both faces.

The core material 2 is formed of-a clad material comprising an interlayer 3 of Invar and copper layers 4, 4 with same cross sectional areas in both faces of the interlayer. Inver is an Fe—Ni alloy containing about 35 to 38 mass % of Ni and is excellent in processibility and has a thermal expansion coefficient of about 1.2×10⁻⁶/° C. (in the case Ni=36.5 mass %), which is greatly lower than 16.5×10⁻⁶/° C. of copper. The ratio of the interlayer 3 and the copper layers 4 composing the core material 2 may be determined so as to adjust the thermal expansion coefficient in the plate face direction approximately same as that of a material of the semiconductor substrate, an object to be soldered thereto, for example silicon (thermal expansion coefficient: 3.5×10⁻⁶/° C.) and in general, the area ratio of the interlayer 3 in the cross section (transverse cross section) in the perpendicular direction to the longitudinal direction of the electrode wire material 1 may be adjusted to be about 20 to 60%. The width and thickness of the core material 2 may properly be determined depending on uses of the electrode wire material and in the case of use as a connection lead wire of a solar cell, the size of the core material is about 1 to 3 mm in width and 0.1 to 0.3 mm in thickness.

The core material 2 is so formed as to have a transverse cross sectional shape like a dish (dish-like cross sectional shape) recessed flatly in the center part of its one surface (the down face in the exemplified illustration). A recessed part 6 for storing molten solder is formed in the recessed side. The hot-dip solder plated layer 5A solidified from the molten solder is filled in the recessed part 6 and its surface is approximately flat. The depth of the recessed part is preferably about 10 to 30 μm in the deepest portion and the width (the opening width in the down face) is preferably about 90% or higher of the width of the core material 2. The upper limit of the width is not particularly limited and the opening may be formed in the entire width of the down face.

The recessed part 6 for storing molten solder can easily be formed by carrying out proper plastic forming or bending forming or the like for the strip-like material (a core raw material) of the clad material. For example, the strip-like material is passed through forming rolls having dish-like cross sectional shape between rolls to easily form the recessed part. Also, in the case the strip-like material is obtained by slitting a plate-like clad material, the gap or the rotational speed of rotary blades of a slitter may be adjusted properly so as to carry out bending forming in the side end parts of the slit strip-like material.

The core material 2 so formed as to be like a dish is washed to have clean surface by acid pickling or with an organic solvent and then the core material 2 is passed through a molten solder bath to provide molten solder in the recessed part 6 of the core material 2. The surface of the molten solder supplied to and filled in the recessed part 6 of the core material 2 is easily made flat since the molten solder filled in the recessed part 6 is prevented from expansion in the center part because of the surface tension as compared with that in the case of forming no recessed part 6 (reference to FIG. 5).

Hence, according to supplying the molten solder so as to be almost fully filled in the recessed part 6, the surface of the molten solder stored in the recessed part 6 in the entire width of the core material 2, namely the surface of the hot-dip solder plated layer 5A after the solidification can be made flat.

To supply the recessed part 6 with the molten solder so as to be almost fully filled, the molten solder bath temperature and the plating speed are properly controlled at the time of molten solder plating or after the core material 2 is dipped in a molten solder bath and pulled out, the excess molten solder rising up in the opening of the recessed part 6 is removed by blowing hot air or scraped out by a proper scraping member.

Alloys usable as the solder material for forming the hot-dip solder plated layers 5A, 5B are Sn-Pb alloy, Sn-0.5 to 5 mass % Ag alloy, Sn-0.5 to 5 mass % Ag-0.3 to 1.0 mass % Cu alloy, Sn-0.3 to 1.0 mass % Cu alloy, Sn-1.0 to 5.0 mass % Ag-5 to 8 mass % In alloy, Sn-1.0 to 5.0 mass % Ag-40 to 50 mass % Bi alloy, Sn-40 to 50 mass % Bi alloy, and Sn-1.0 to 5.0 mass % Ag-40 to 50 mass % Bi-5 to 8 mass % In alloy respectively a melting point of about 130 to 300° C. Since Pb is harmful for human being and possibly pollutes the natural environments, in terms of pollution prevention, Sn—Ag alloy, Sn—Ag—Cu alloy, Sn—Cu alloy, Sn—Ag—In alloy, and Sn—Ag—Bi alloy free of Pb respectively are preferable for the solder material. Also, these respective solder materials may contain one ore more elements selected from about 50 to 200 ppm of P, several to several tens ppm of Ga, several to several tens ppm of Gd, and several to several tens ppm of Ge. The hot-dip solder plated layers 5A, 5B may be made to have multilayer structure by using a variety of pure metals such as Sn, Ag and Cu, or their alloys. In such a case, the thickness of the respective layers is adjusted so as to be a prescribed alloy after melting. Such a multilayer structure is advantageous in a point that the components of the desired solder material can easily be adjusted by simply adjusting the thickness of the respective layers. The multilayer structure can be formed easily by successively carrying out metal plating.

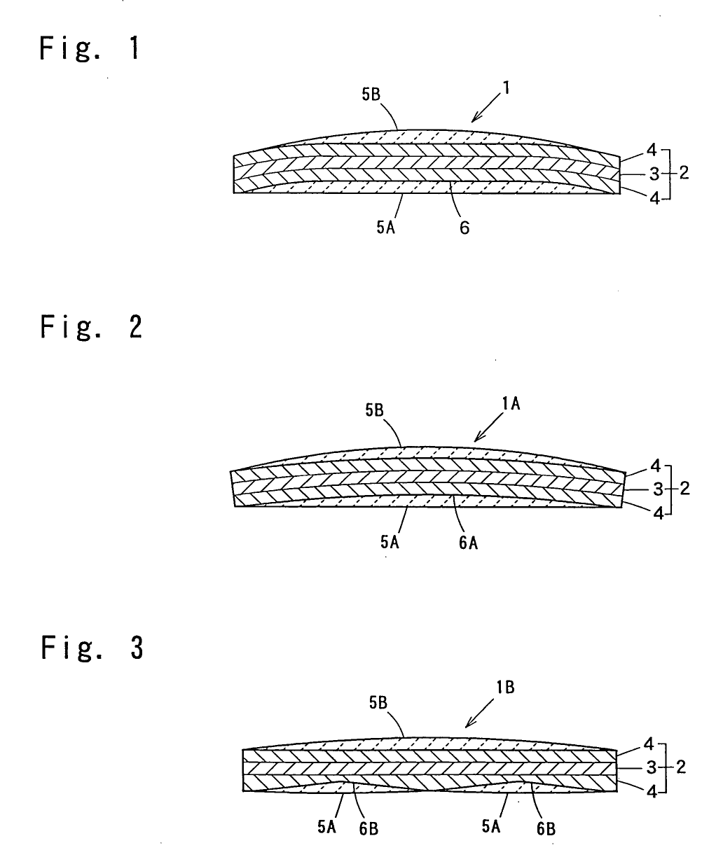

In the above-mentioned embodiment, the core material 2 has a dish-like shape as the transverse cross sectional shape of which the center bottom part of the recessed part 6 is flat, but the cross sectional shape of the core material is not particularly limited to such a shape and just like the electrode wire material 1A shown in FIG. 2, the cross section shape of the core material 2 may be curved as a whole. In such a case, the recessed part 6A for storing molten solder has a bottom face with curved cross-section. Also, just like the electrode wire material 1B shown in FIG. 3, the cross section shape may have two partial recessed parts 6B, 6B with triangular cross sectional shape in the copper layer 4 in the down face side of the core material 2. In this case, the recessed part for storing molten solder is composed of these partial recessed parts 6B, 6B. The partial recessed parts 6B, 6B can be formed easily by passing a strip-like plate of a clad material through forming rolls of which one has triangularly projected parts in the roll surface and pressurizing the strip-like plate by the forming rolls. Of course, the cross-sectional shapes of the partial recessed parts and the number of these parts are not limited as illustrated and proper shapes and number may be selected. In the embodiments shown in FIG. 2 and FIG. 3, the same reference numerals are assigned to the same constituents of the electrode wire material 1 of the embodiment of FIG. 1.

In the electrode wire materials 1, 1A, and 1B according to the above-mentioned embodiments, a clad material composed of an interlayer 3 composed of a Fe-35 to 38 mass % Ni alloy and copper layers 4, 4 formed on both faces of the interlayer 3 is used for the core material 2. The interlayer may be composed of a Fe-29 to 37 mass % Ni-6 to 18 mass % Co alloy with a low expansion coefficient such as Kovar (trade name) or pure Fe. The core material may entirely be composed of a copper material, but when the core material is formed of the clad material (particularly, of which the interlayer is composed of a low thermal expansion Fe alloy such as Fe—Ni alloy or a Fe—Ni—Co alloy), the thermal expansion coefficient of the material is made similar to that of a semiconductor such as silicon and then the thermal stress can be lessened further at the time of soldering the electrode wire material to the semiconductor substrate.

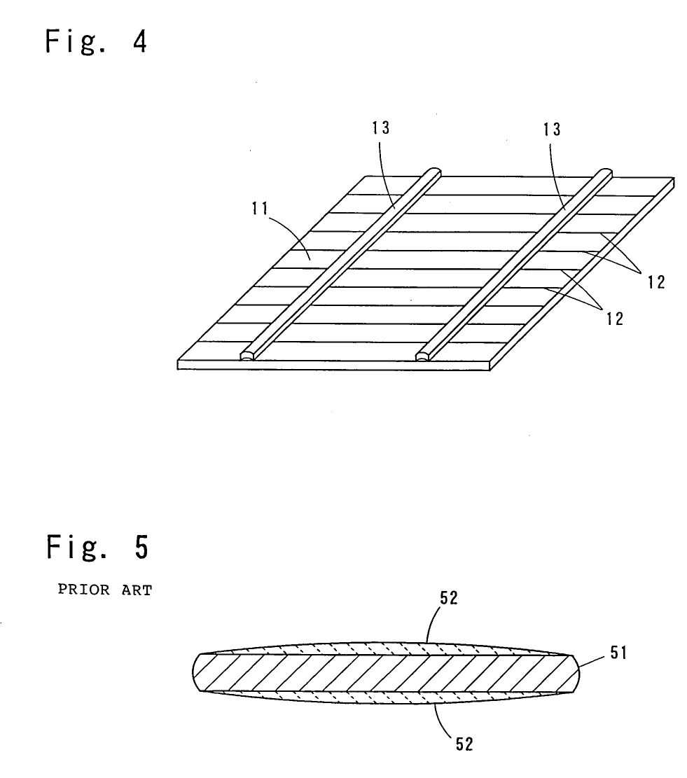

FIG. 4 shows a solar cell of which connection lead wires are formed of the electrode wire material 1 according to the first embodiment. The solar cell comprises a semiconductor substrate 11 of a silicon semiconductor having PN junction and connection lead wires 13 soldered to a plurality of front face electrodes 12 formed linearly on the surface of the semiconductor substrate 11. The semiconductor substrate 11 has rear face electrodes formed on the rear face of it.

On the semiconductor substrate 11 before the connection lead wires 13 being soldered, solder belts are arranged at right angles to a plurality of the front face electrodes 12 so as to connect to the front face electrodes 12. Along the solder belt, the electrode wire material 1 is mounted on the semiconductor substrate 11 so as to make the hot-dip solder plated layer 5A of the electrode wire material 1 to contact with the solder belt. And the solder belt on the semiconductor substrate 11 and the hot-dip solder plated layer 5A of the electrode wire material 1 are melted together to solder the electrode wire material 1 on the surface of the semiconductor substrate 11. Accordingly, the connection lead wires 13 formed of the electrode wire material 1 can be bonded to the semiconductor substrate 11.

According to the solar cell, since the hot-dip solder plated layer 5A of the electrode wire material 1 is filled in the recessed part 6 and made the surface flat to obtain excellent solderability, the connection lead wires 13 are firmly bonded to the semiconductor substrate 11. Hence, the connection lead wires hardly come out of the semiconductor substrate and are excellent in durability. As the connection lead wires 13 in the solar cell, not only the electrode wire material 1 of the first embodiment but also electrode wire materials 1A, 1B according to other embodiments can be used and similar effects can be brought by using any of these electrode wire materials.

Hereinafter, the electrode wire material of the invention will be described more specifically by way of examples thereof, however it should be understand that the invention be limited to the examples.

### EXAMPLES

A clad material (0.18 mm thick) comprising a middle layer with a thickness of 60 μm composed of Invar (Fe-36.5 mass % Ni) and copper layers with each thickness of 60 μm formed on both faces of the interlayer was prepared. Strip-like materials with each width of 2 mm were produced from the clad material by a slitter and the strip-like materials were further cut into pieces with each length of 40 mm to obtain core materials related to examples. When slitting by the slitter, the intervals of rotary blades were adjusted so as to carry out bending forming in the end parts in the width direction of the each strip-like material to make the transverse cross sectional shape of the core material dish-like as shown in FIG. 1. The cross-sectional shape was observed by an optical microscope (magnification about 200 times) to find that the deepest depth in the recessed part formed in the recessed side of the core material was about 20 μm and the opening width of the recessed part was about 95% of the core material width. On the other hand, core materials with each length of 40 mm related to comparative examples were produced from a pressed flat wire with a thickness of 0.18 mm and a width of 2 mm composed of copper.

After these core materials were cleaned in the surface with an organic solvent (acetone), each of the core materials was dipped in a molten solder bath (solder composition: Sn-3.5 mass % Ag; melting point: 220° C., and bath temperature: 300° C.) and quickly pulled out to form hot-dip solder plated layer on the surface of the core material. After this manner, an electrode wire material was obtained. With respect to the electrode wire materials of the examples, each hot-dip solder plated layer was filled in the recessed part and almost flat in the surface in the entire width of the core material. On the other hand, each of the electrode wire materials of the comparative examples, as shown in FIG. 5, showed a hill-like shape expanded in the center part from side end parts of the core material.

The electrode wire materials of the examples and comparative examples produced in such a manner were coated with a proper amount of a flux (NS-30, manufactured by Nihon Superior Co., Ltd.). Each electrode wire material was mounted on an oxygen-free copper strip plate (0.5 mm thick, 4 mm wide, and 40 mm long) in such a manner that the hot-dip solder plated layer got contact with the center part in the width direction of the copper strip plate along the longitudinal direction. The copper strip plate and the electrode wire material thereon were put on the hot plate and heated (kept at 260° C. for 1 minute) to solder the electrode wire material to the copper strip plate.

After that, the electrode wire material and copper strip plate being pulled in the opposed directions with a tensile tester to peel the electrode wire material from the copper plate, the tensile force required for peeling was measured. The test was repeated 5 times for each sample and the average value was calculated. As a result, the tensile force was 14.1 N for the examples and 8.1 N for the comparative examples. Accordingly, the electrode wire materials of the examples had joining force of about 1.7 times as compared to that of the electrode wire materials of the comparative example and thus it was confirmed that the electrode wire materials of the examples had excellent solderability.

1-8. (canceled)

9. An electrode wire material comprising:
a core material made of a strip-like conductive material; and
a hot-dip solder plated layer disposed on a surface of the core material; wherein
the core material has a recessed portion arranged to store molten solder along a longitudinal direction thereof and the hot-dip solder plated layer is located in the recessed portion.

10. The electrode wire material according to claim 9, wherein the recessed portion has an opening width in a lateral direction of the core material of about 90% or more of the width of the core material.

11. The electrode wire material according to claim 10, wherein the recessed portion is formed in the recessed side of the core material having a dish-like or curved shape in cross section in a direction that is substantially perpendicular to the longitudinal direction.

12. The electrode wire material according to claim 9, wherein the core material is made of a clad material including an interlayer of a low thermal expansion Fe alloy selected from an Fe—Ni alloy or Fe—Ni—Co alloy and copper layers disposed on both surfaces of the interlayer.

13. The electrode wire material according to claim 9, wherein the hot-dip solder plated layer is composed of a solder material having a melting point of about 130° C. or higher and about 300° C. or lower and free of lead.

14. A solar cell comprising:
a semiconductor substrate made of a semiconductor having a PN junction; and
a connection lead wire soldered to a plurality of front surface electrodes disposed on the surface of the semiconductor substrate; wherein
the connection lead wire is made of the electrode wire material according to claim 1, the electrode wire material being soldered to the plurality of the front surface electrodes via the hot-dip solder plated layer.

15. The solar cell according to claim 14, wherein the core material of the electrode wire material is made of a clad material including an interlayer of a low thermal expansion Fe alloy selected from an Fe—Ni alloy or Fe—Ni—Co alloy and copper layers disposed on both surfaces of the interlayer.

16. The solar cell according to claim 14, wherein the hot-dip solder plated layer of the electrode wire material is composed of a solder material having a melting point of about 130° C. or higher and about 300° C. or lower and free of lead.
